(19) United States
(12) Patent Application Publication
(10) Pub. No.: US 2025/0133777 A1
(43) Pub. Date: Apr. 24, 2025

(54) SEMICONDUCTOR DEVICE AND MANUFACTURING METHOD THEREOF

(71) Applicant: NANYA TECHNOLOGY CORPORATION, New Taipei city (TW)

(72) Inventors: Yen-Wei YEH, Taoyuan City (TW); Ji-Feng LIU, New Taipei City (TW)

(21) Appl. No.: 18/491,777

(22) Filed: Oct. 22, 2023

(51) Int. Cl. H01L 29/10; H01L 21/02; H01L 21/28; H01L 21/285; H01L 29/161; H01L 29/45; H01L 29/49

(52) U.S. Cl. CPC H10D 30/751; H01L 21/02532; H01L 21/28088; H01L 21/28568; H10D 62/832; H10D 64/62; H10D 64/667

(57) ABSTRACT

A semiconductor device includes a substrate, a channel layer, a source/drain region and a gate structure. The channel layer is located on the substrate, in which the channel layer includes silicon germanium. The source/drain region is adjacent to the channel layer. The gate structure is located on the channel layer, in which the gate structure includes a dielectric layer and a work function metal layer. The dielectric layer is located on the channel layer. The work function metal layer is located on the dielectric layer.

### BACKGROUND

### Field of Disclosure

The present disclosure relates to a semiconductor device and a manufacturing method of a semiconductor device.

### Description of Related Art

As is well known, a MOSFET (Metal-Oxide-Semiconductor Field-Effect Transistor) employs a gate-modulated conductive channel of n-type or p-type conductivity, and is accordingly referred to as an “NMOS” or “PMOS”, respectively. In the operation of a MOSFET device, higher drive current means better device performance. In order to increase the drive current of a MOSFET device, one common way is to exert a compressive force to the channel between source/drain regions, which can be done by multiple methods.

### SUMMARY

One aspect of the present disclosure provides a manufacturing method of a semiconductor device.

According to some embodiments of the present disclosure, a semiconductor device includes a substrate, a channel layer, a source/drain region and a gate structure. The channel layer is located on the substrate, in which the channel layer includes silicon germanium. The source/drain region is adjacent to the channel layer. The gate structure is located on the channel layer, in which the gate structure includes a dielectric layer and a work function metal layer. The dielectric layer is located on the channel layer. The work function metal layer is located on the dielectric layer.

In some embodiments of the present disclosure, the substrate has a different lattice constant from the channel layer.

In some embodiments of the present disclosure, the gate structure further includes an interface layer. The interface layer is located between the dielectric layer and the channel layer.

In some embodiments of the present disclosure, the interface layer partially overlaps the source/drain region in a vertical direction.

In some embodiments of the present disclosure, the gate structure further includes a fill layer. The fill layer is located on the work function metal layer.

In some embodiments of the present disclosure, the semiconductor device further includes a capping layer. The capping layer is located between the channel layer and the gate structure.

In some embodiments of the present disclosure, the substrate includes silicon.

Another aspect of the present disclosure provides a semiconductor device.

According to some embodiments of the present disclosure, a semiconductor device includes a substrate, a channel layer, a source/drain region and a gate structure. The channel layer is located on the substrate, in which the channel layer includes silicon germanium and is configured to exert a compressive force. The source/drain region is adjacent to the channel layer. The gate structure is located on the channel layer.

In some embodiments of the present disclosure, the semiconductor device further includes an interlayer dielectric layer. The interlayer dielectric layer is located on the substrate and the gate structure.

In some embodiments of the present disclosure, the interlayer dielectric layer surrounds the gate structure.

In some embodiments of the present disclosure, the semiconductor device further includes a first conductive contact. The first conductive contact is located on the source/drain region.

In some embodiments of the present disclosure, the semiconductor device further includes a second conductive contact. The second conductive contact is located on the gate structure, in which the second conductive contact includes different material from the first conductive contact.

In some embodiments of the present disclosure, the first conductive contact includes tungsten and the second conductive contact includes tungsten and cobalt.

Another aspect of the present disclosure provides a manufacturing method of a semiconductor device.

According to some embodiments of the present disclosure, a manufacturing method of a semiconductor device includes forming a source/drain region in a substrate; growing an channel layer over the substrate, in which the channel layer directly contacts the substrate and includes silicon germanium; and forming a gate structure on the channel layer.

In some embodiments of the present disclosure, growing the channel layer over the substrate further includes simultaneously growing the channel layer over the substrate and the source/drain region and etching the channel layer to expose the source/drain region.

In some embodiments of the present disclosure, the manufacturing method of the semiconductor device further includes controlling a thickness of the channel layer.

In some embodiments of the present disclosure, forming the gate structure on the channel layer further includes forming a dielectric layer over the channel layer; forming a work function metal layer over the dielectric layer; and forming a fill layer over the work function metal layer.

In some embodiments of the present disclosure, forming the gate structure on the channel layer further includes before forming the dielectric layer, forming an interface layer over the channel layer, wherein the interface layer partially overlaps with the source/drain region in a vertical direction.

In some embodiments of the present disclosure, the manufacturing method of the semiconductor device further includes forming an interlayer dielectric layer on the substrate and the gate structure.

In some embodiments of the present disclosure, the manufacturing method of the semiconductor device further includes forming a plurality of openings in the interlayer dielectric layer; and forming a first conductive contact and a second conductive contact in the openings respectively, in which the second conductive contact includes different material from the first conductive contact.

In the aforementioned embodiments of the present disclosure, since the channel layer includes silicon germanium, which has a larger lattice constant than the substrate that includes silicon, the channel layer can exert a compressive force, which increases the channel mobility and thus increases the drive current of the transistor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor device according to one embodiment of the present disclosure.

FIG. 2 to FIG. 3 are cross-sectional views of the semiconductor device of FIG. 1 at intermediate steps of the manufacturing method according to one embodiment of the present disclosure.

FIG. 4 is a critical thickness-germanium content diagram of the channel layer of FIG. 4.

FIG. 5 to FIG. 11 are cross-sectional views of the semiconductor device of FIG. 1 at intermediate steps of the manufacturing method after the step of FIG. 4.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the drawings. The spatially relative terms are intended to encompass different orientations of the device in use or operation in addition to the orientation depicted in the drawings. The apparatus may be otherwise oriented (rotated 90 degrees or at other orientations) and the spatially relative descriptors used herein may likewise be interpreted accordingly.

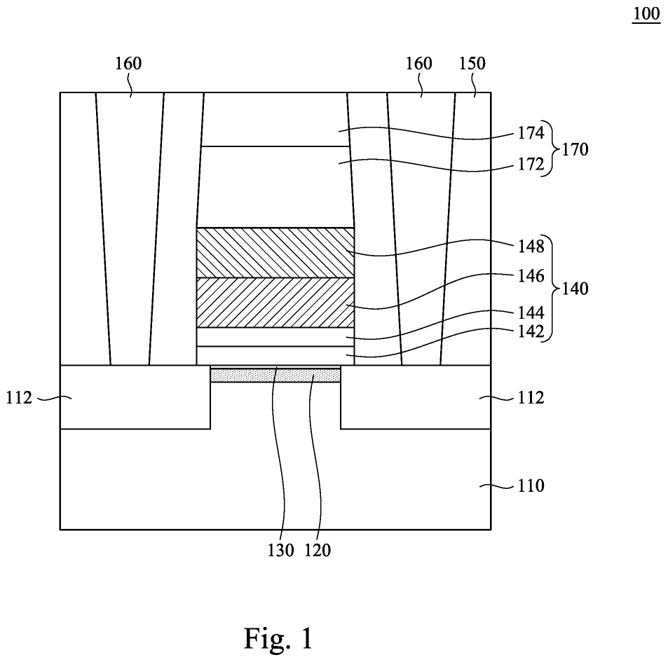

FIG. 1 is a cross-sectional view of a semiconductor device 100 according to one embodiment of the present disclosure. Refer to FIG. 1, a semiconductor device 100 includes a substrate 110, a channel layer 120, at least a source/drain region 112 and a gate structure 140. The channel layer 120 is located directly on the substrate 110, in which the channel layer 120 includes silicon germanium (SiGe) and is configured to exert a compressive force. The source/drain regions 112 are adjacent to the two sides of the channel layer 120. The gate structure 140 is located on the channel layer 120, in which the gate structure includes a dielectric layer 144, a work function metal layer 146 and a fill layer 148. The dielectric layer 144 is located on the channel layer 120. The work function metal layer 146 is located on the dielectric layer 144. The fill layer 148 is located on the work function metal layer 146. In general, the semiconductor device 100 is often refer to as a high-k metal gate (HKMG) PMOS transistor, in which the dielectric layer 144 includes dielectric material(s) with a dielectric constant greater than 3.9. Such dielectric material includes hafnium oxide (HfO₂), aluminum oxide (Al₂O₃), titanium oxide (TiO₂), tantalum oxide (Ta₂O₅), zirconium oxide (ZrO₂), lanthanum oxide (La₂O₃), cerium oxide (CeO₂), bismuth silicate (Bi₂Si₂O₁₂), tungsten oxide (WO₃), yttrium oxide (Y₂O₃), lanthanum aluminate (LaAlO₃), barium strontium titanate (BaₓSrₓTiO₃), strontium titanate (SrTiO₃), lead zirconate (PbZrO₃), lead scandium tantalite (PST), lead zinc niobate (PZN), lead zirconate titanate (PZT), lead magnesium niobate (PMN), a combination thereof, or the like. As an example, the dielectric constant of hafnium oxide is in the range between 16 and 19.

In the operation of the semiconductor device 100, the compressive force exert to the channel layer 120 can drastically improve the carrier mobility of the channel, and thus the drive current. In general, the drive current I_{d} of a PMOS satisfies:

$${I}_{d} = \frac{1}{2} {μ}_{n} {C}_{o x} \frac{W}{L} ( {V}_{g s} - {V}_{t} ) \qquad Eq .$$

In which μₙ is the carrier mobility of the channel, Cₒₓ is the capacitance density, W stands for channel width, L stands for channel length, V_{gs} is the gate-source voltage of the semiconductor device 100, Vₜ is the threshold voltage of the semiconductor device 100. The equation shows that the carrier mobility of the channel is proportional to the drive current. In the present embodiment, the method to exert the compressive force to the channel layer 120 is by growing an epitaxial SiGe channel layer 120 on the substrate 110. Therefore, the substrate 110 has a different lattice constant from the channel layer 120, in which the substrate 110 includes silicon and the channel layer 120 includes SiGe. Due to larger lattice constant of epitaxial SiGe when grow on the silicon-based substrate 110, the channel layer 120 that includes SiGe can exert a compressive force, therefore increases the carrier mobility of the channel layer 120.

Still refer to FIG. 1, the gate structure 140 further includes an interface layer 142. The interface layer 142 is located between the dielectric layer 144 and the channel layer 120. The interface layer 142 partially overlaps the source/drain region 112 in a vertical direction. The interface layer 142 includes silicon dioxide or similar dielectric materials. In some embodiments, the gate structure 140 can further includes spacer structures (not shown) to have a better electrical isolation between the gate structure 140 and the source/drain region 112. In some embodiments, the semiconductor device 100 further includes a capping layer 130, an interlayer dielectric (ILD) layer 150, two first conductive contact 160 and a second conductive contact 170. The capping layer 130 is located between the channel layer 120 and the gate structure 140. The interlayer dielectric layer 150 is located on the substrate 110 and the gate structure 140 and surrounds the gate structure 140. The first conductive contacts 160 are located on each of the source/drain region 112 respectively. The second conductive contact 170 is located on the gate structure 140, in which the second conductive contact 170 includes different material from the first conductive contact 160. In the present embodiment, the second conductive contact 170 is a bilayer structure that has a bottom contact 172 and a top contact 174. In some embodiments, the first conductive contact 160 includes tungsten (W) and the second conductive contact includes tungsten and cobalt (Co).

It is to be noted that the connection relationships, the materials, and the advantages of the elements described above will not be repeated in the following description. In the following description, a manufacturing method of the semiconductor device 100 is described.

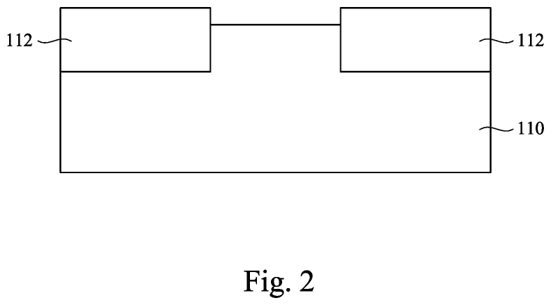

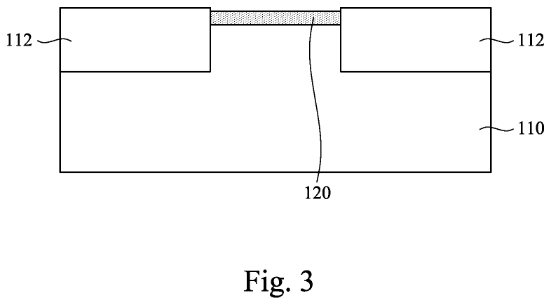

FIG. 2 to FIG. 3 are cross-sectional views of the semiconductor device 100 of FIG. 1 at intermediate steps of the manufacturing method according to one embodiment of the present disclosure. Refer to FIG. 2, the manufacturing method of the semiconductor device 100 includes forming a source/drain region 112 in a substrate 110. The source/drain region 112 can be formed using deposition process such as chemical vapor deposition (CVD), metal-organic chemical vapor deposition (MOCVD), physical vapor deposition (PVD), atomic layer deposition (ALD), ion implantation, a combination thereof or other similar methods.

Refer to FIG. 3, thereafter, growing a channel layer 120 over the substrate 110, in which channel layer 120 directly contacts the substrate 110 and includes silicon germanium. The channel layer 120 may be an epitaxial layer. In some embodiments, this step includes simultaneously growing the channel layer 120 over the substrate 110 and the source/drain region 112 and etching the channel layer 120 to expose the source/drain region 112. The step is referred to as a “selective growth” of the epitaxial layer, in which the two steps described above (epitaxial growth and etching) are performed simultaneously, and thereby “selectively” grows the channel layer 120 only on the exposed area of the substrate 110. Optimally, the etching rate and the growth rate are controlled such that the channel layer 120 doesn't grow on the source/drain region 112. In this embodiment, this step further includes a pre-clean step before the selective epitaxial growth step. Such pre-clean step includes a wet cleaning step and a baking step to clean the surface of the substrate 110 and to let the channel layer 120 grows directly on the substrate 110. The etching process is performed with hydrogen chloride (HCl) gas and is an in-situ process.

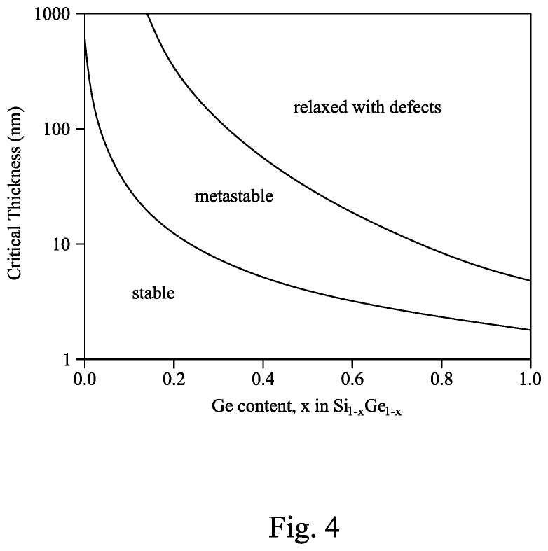

FIG. 4 is a critical thickness-germanium content diagram of the channel layer 120 of FIG. 3. Refer to FIG. 4, when growing the channel layer 120, the thickness affects the performance of the channel layer 120, so the thickness of the channel layer 120 should be controlled. If the thickness is greater than the critical thickness (the upper bound of the stable area), the SiGe epitaxy will dislocate due to strain relaxation of the compressed lattice, which will cause the desired compressive force exerted to the channel layer 120 to decrease. By controlling the temperature and the silicon-germanium ratio of epitaxial process, the critical thickness can be enlarged at low growth temperature and low germanium concentration, such that the thickness of the channel layer 120 can be controlled in a bigger tolerance region. In addition, the area of the exposed portion of the substrate 110 can also vary the process. If the exposed portion of the substrate 110 is too small, the concentration of the gas in epitaxial process needs to be maintain in a rather low concentration to prevent the thickness exceed the critical thickness. Moreover, the etching process needs to consider the loading effect, in which the density of the pattern to be grown needs to be designed uniformly to prevent the etching rate difference between the dense area and the thin area, thereby having a uniform thickness of the channel layer 120.

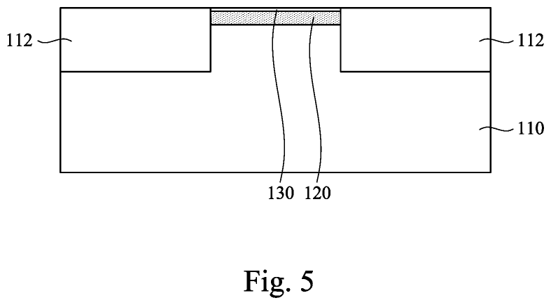

FIG. 5 to FIG. 11 are cross-sectional views of the semiconductor device of FIG. 1 at intermediate steps of the manufacturing method after the step of FIG. 3. Refer to FIG. 5, after the step of FIG. 3, forming a capping layer 130 on the channel layer 120. In some embodiments, the capping layer 130 includes silicon.

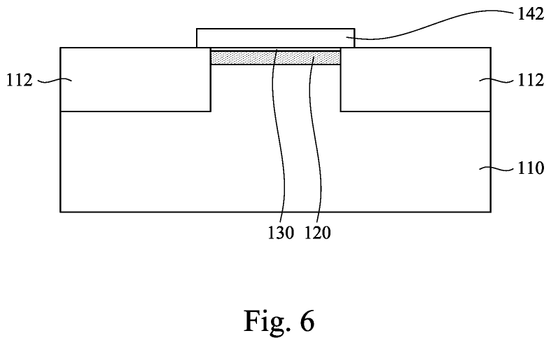

Refer to FIG. 6, thereafter, forming an interface layer 142 on the capping layer 130, in which the interface layer 142 partially overlaps with the source/drain region 112 in the vertical direction. In some embodiments, the interface layer 142 includes silicon dioxide, and can be formed using chemical vapor deposition (CVD), atomic layer deposition (ALD), or the like. In some embodiments, the formation of the interface layer 142 further includes a pattering process.

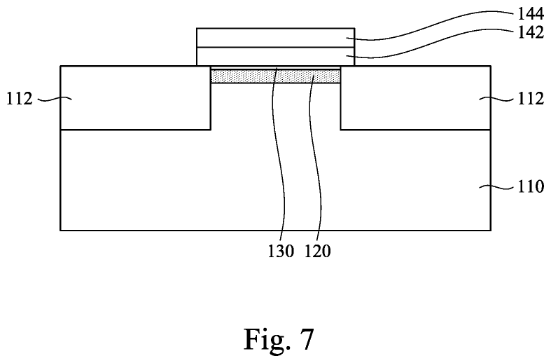

Refer to FIG. 7, thereafter, forming a dielectric layer 144 on the interface layer 142. The dielectric layer 144 includes high-k dielectric material(s) and can be formed using chemical vapor deposition (CVD), metal-organic chemical vapor deposition (MOCVD), physical vapor deposition (PVD), atomic layer deposition (ALD), or the like.

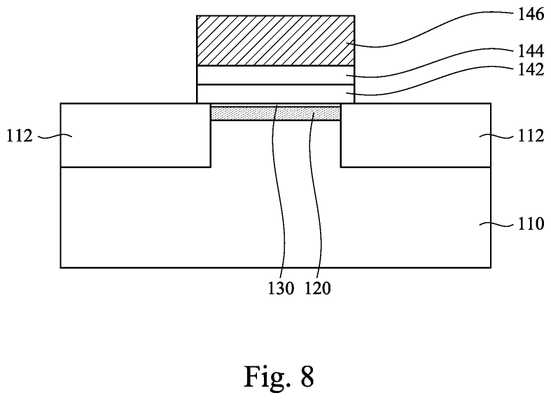

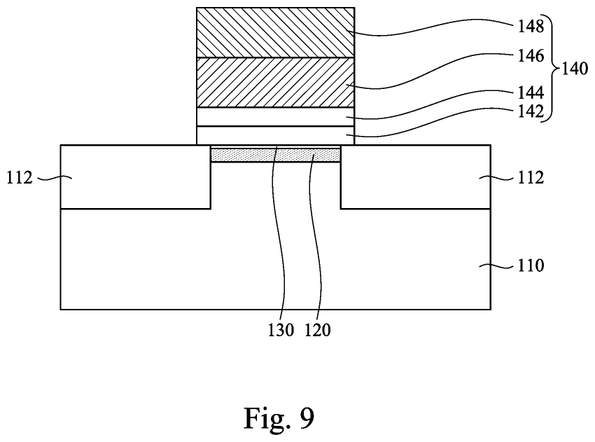

Refer to FIG. 8 and FIG. 9, thereafter, forming a work function metal layer 146 over the dielectric layer 144. Thereafter, forming a fill layer 148 over the work function metal layer 146, and hence the gate structure 140 is formed. The work function metal layer 146 includes materials such as titanium nitride (TiN) and can be formed using atomic layer deposition (ALD), chemical vapor deposition (CVD), physical vapor deposition (PVD) or the like. The work function metal layer 146 includes materials such as titanium nitride (TiN) and can be formed using atomic layer deposition (ALD), chemical vapor deposition (CVD), physical vapor deposition (PVD) or the like. The fill layer 148 includes materials such as polysilicon.

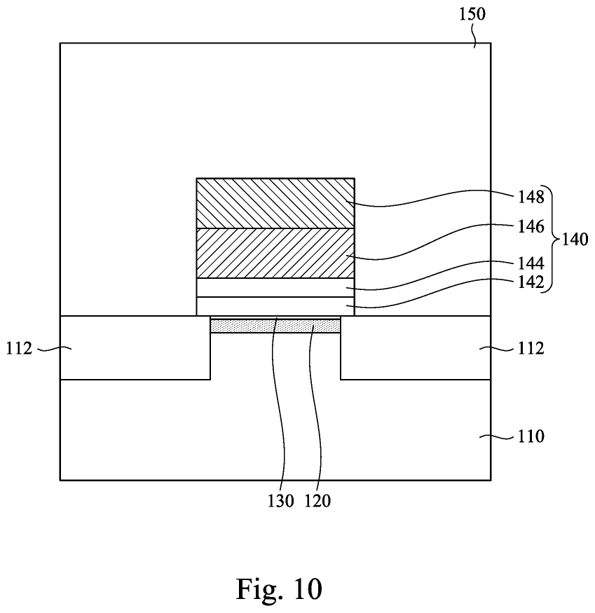

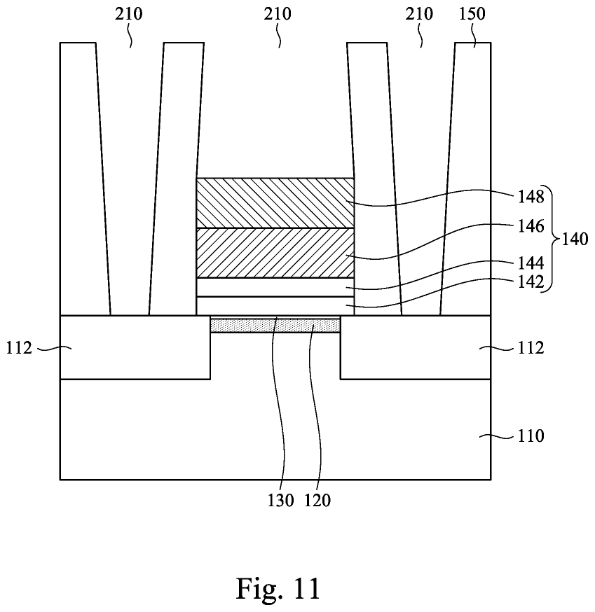

Refer to FIG. 10 and FIG. 11, thereafter, forming an interlayer dielectric layer 150 on the substrate 110 and the gate structure 140. The interlayer dielectric layer 150 can include materials such as phosphosilicate glass (PSG), borophosphosilicate glass (BPSG), fluorinated silicate glass (FSG), undoped silicate glass (USG), silicon oxycarbide (SiOxCy), spin-on glass (SOG), spin-on-polymers, carbon-doped silicon material, a combination thereof, or the like, and can be formed using spin-on coating, chemical vapor deposition, or other similar method. Thereafter, forming openings 210 in the interlayer dielectric layer 150.

Refer to FIG. 1, thereafter, forming first conductive contacts 160 and a second conductive contact 170 in the openings respectively, in which the second conductive contact 170 includes different material from the first conductive contact 160.

In summary, since the channel layer 120 includes silicon germanium, which has a larger lattice constant than the substrate 110 that includes silicon, the channel layer 120 can exert an internal compressive force, which increases the channel mobility and thus increases the drive current of the transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a channel layer located on the substrate, wherein the channel layer comprises silicon germanium;
a source/drain region adjacent to the channel layer; and
a gate structure located on the channel layer, wherein the gate structure comprises:
a dielectric layer located on the channel layer; and
a work function metal layer located on the dielectric layer.

2. The semiconductor device of claim 1, wherein the substrate has a different lattice constant from the channel layer.

3. The semiconductor device of claim 1, wherein the gate structure further comprises:
an interface layer located between the dielectric layer and the channel layer.

4. The semiconductor device of claim 3, wherein the interface layer partially overlaps the source/drain region in a vertical direction.

5. The semiconductor device of claim 1, wherein the gate structure further comprises:
a fill layer located on the work function metal layer.

6. The semiconductor device of claim 1, further comprising:
a capping layer located between the channel layer and the gate structure.

7. The semiconductor device of claim 1, wherein the substrate comprises silicon.

8. A semiconductor device, comprising:
a substrate;
a channel layer located on the substrate, wherein the channel layer comprises silicon germanium and is configured to exert a compressive force;
a source/drain region adjacent to the channel layer; and
a gate structure located on the channel layer.

9. The semiconductor device of claim 8, further comprising:
an interlayer dielectric layer located on the substrate and the gate structure.

10. The semiconductor device of claim 9, wherein the interlayer dielectric layer surrounds the gate structure.

11. The semiconductor device of claim 8, further comprising:
a first conductive contact located on the source/drain region.

12. The semiconductor device of claim 11, further comprising:
a second conductive contact located on the gate structure, wherein the second conductive contact comprises different material from the first conductive contact.

13. The semiconductor device of claim 12, wherein the first conductive contact comprises tungsten and the second conductive contact comprises tungsten and cobalt.

14. A manufacturing method of a semiconductor device, comprising:
forming a source/drain region in a substrate;
growing a channel layer over the substrate, wherein the channel layer directly contacts the substrate and comprises silicon germanium; and
forming a gate structure on the channel layer.

15. The manufacturing method of the semiconductor device of claim 14, wherein growing the channel layer over the substrate further comprises:
simultaneously growing the channel layer over the substrate and the source/drain region and etching the channel layer to expose the source/drain region.

16. The manufacturing method of the semiconductor device of claim 14, further comprising:
controlling a thickness of the channel layer.

17. The manufacturing method of the semiconductor device of claim 14, wherein forming the gate structure on the channel layer further comprises:
forming a dielectric layer over the channel layer;
forming a work function metal layer over the dielectric layer; and
forming a fill layer over the work function metal layer.

18. The manufacturing method of the semiconductor device of claim 17, wherein forming the gate structure on the channel layer further comprises:
before forming the dielectric layer, forming an interface layer over the channel layer, wherein the interface layer partially overlaps with the source/drain region in a vertical direction.

19. The manufacturing method of the semiconductor device of claim 14, further comprising:
forming an interlayer dielectric layer on the substrate and the gate structure.

20. The manufacturing method of the semiconductor device of claim 19, further comprising:
forming a plurality of openings in the interlayer dielectric layer; and
forming a first conductive contact and a second conductive contact in the openings respectively, wherein the second conductive contact comprises different material from the first conductive contact.
